(19) United States
(12) Patent Application Publication
(10) Pub. No.: US 2002/0102840 A1
(43) Pub. Date: Aug. 1, 2002

(54) Method for manufacturing cooper interconnects by using a cap layer

(76) Inventors: Teng-Chun Tsai, Hsin-Chu City (TW); Chai-Lin Hsu, Taipei City (TW); Yung-Tsung Wei, Pai-Ho Chen (TW); Ming-Sheng Yang, Hsin-Chu City (TW)

Correspondence Address: Powell, Goldstein, Frazer & Murphy, LLP, 1001 Pennsylvanic Avenue, Suite 600, Washington, DC, 20004, US

(21) Appl. No.: 09/774,464

(22) Filed: Jan. 31, 2001

(51) Int. Cl. H01L 21/4763; H01L 21/44

(52) U.S. Cl. 438/638; 438/627; 438/633; 438/687; 438/622

(57) ABSTRACT

The present invention provides a method to form a copper interconnect and avoid a dishing phenomenon on the copper interconnect in the manufacturing process which will cause the metal line thinning and high resistance. By using a cap layer selectively positioned over the dual damascene structure, the method can balance the difference of polishing rate between the copper and the surrounding material. Such we can get a plane surface of interconnect in a chemical mechanical polishing process.

### BACKGROUND

1. Field of the Invention

The present invention generally relates to a method for manufacturing copper interconnects, and in particular to a method for manufacturing copper interconnects without dishing on the surface of interconnects.

2. Description of the Prior Art

As semiconductor device dimensions are scaled down to submicron feature sizes, the copper interconnect process has become an important manufacturing method. It is due to that the copper with low resistivity can reduce RC delay and enhance electromigration. Moreover, the dual damascene technique is now the primary method to manufacture the copper interconnect. A prior method for forming a multi-level copper interconnect approximately comprises the following steps: firstly, as shown in FIG. 1A, there is a copper interconnect 101 over a substrate (not shown). Secondly, an insulating layer 102 is deposited to cover the copper interconnect 101, and then is etched to form a dual damascene opening. A barrier layer 103, such as tantalum or tantalum nitride, is then deposited on the surface of the dual damascene opening. Next, a copper layer 104 is deposited to fill up the dual damascene opening. Finally, the redundant copper and barrier layer over the insulating layer 102 are removed and the multi-level copper interconnect is completed. In practical process, the redundant copper and barrier layer over the insulating layer 102 can be removed by chemical-mechanical polishing (CMP). Because the polishing rate of copper is larger than that of the material around the copper, such as a barrier layer, a dishing phenomenon occurs on the surface of the copper interconnect. As shown in FIG. 1B, a concave 106 is formed on the surface of the copper interconnect 105 and will cause metal line thinning and high resistance. The problems caused by dishing phenomenon are more serious in a broader interconnect and a larger area of copper.

Besides, as the inter-metal dielectric (IMD) layer is composed of a low-K material, a passivation layer, such as a layer of silicon nitride or silicon carbide, is usually deposited on the IMD layer to prevent a scrape on the surface of IMD layer caused by a polishing and an alteration in the property of IMD layer caused by a contact with the slurry. As shown in FIG. 2A, an low-K dielectric layer 202 is deposited on the copper interconnect 201. Next, a passivation layer 203 is deposited on the dielectric layer 202. The dielectric layer 202 and the passivation layer 203 are then etched to form a dual damascene opening. Then, a barrier layer 204, such as tantalum or tantalum nitride, is deposited on the surface of the dual damascene opening. Next, a copper layer 205 is deposited to fill up the dual damascene opening. Finally, the redundant copper and barrier layer over the passivation layer 203 are removed and the multi-level copper interconnect is completed. As mentioned above, however, the polishing rate of copper is larger than that of the material around the copper, a dishing phenomenon occurs on the surface of the copper interconnect. As shown in FIG. 2B, a concave 207 is formed on the surface of the copper interconnect 206. And partial region 208 of the low-K dielectric layer 202 is exposed, such will cause variances in the property of the low-K dielectric layer 202.

Thus, the dishing phenomenon is a serious problem in the copper interconnect process and is required to be solved instantly.

### SUMMARY

It is an object of the invention to provide a method for forming a copper interconnect.

It is another object of the invention to provide a method to avoid a dishing phenomenon in the manufacturing process of copper interconnect which will cause the metal line thinning, high resistance, and variances in property of a low-K dielectric material.

According to the foregoing objects, the present invention provides a method to balance the difference of polishing rate between the copper and the surrounding material by using a cap layer selectively positioned over the dual damascene structure. Such can get a plane surface in a chemical mechanical polishing. The detail steps are described as following: firstly, an dielectric layer, such as silicon oxide and low-K materials, is deposited on a copper interconnect. If the dielectric layer is a layer of low-K material, a passivation layer, such as silicon nitride and silicon carbide, is necessary and deposited on the surface of the dielectric layer. Then, the dielectric layer is etched to form a dual damascene opening. Next, a barrier layer, such as tantalum and tantalum nitride, is deposited on the surface of the dual damascene opening. A copper layer is then deposited to fill up the dual damascene opening. Next, a cap layer is deposited on the surface of the copper layer. The material of the cap layer can be metal, polysilicon, silicon oxide, silicon nitride, silicon carbide, spin-on glass, or low-K materials. Then, a photoresist is deposited and patterned to form a photoresist mask. The photoresist mask is over the dual damascene opening, and the width of the photoresist mask is about equal to the width of the dual damascene opening. Next, an etching is performed to remove a part of the cap layer which is not covered with the photoresist mask and the residue of the cap layer is over the dual damascene opening. Then the photoresist mask is removed. A chemical mechanical polishing is performed to remove the residue of the cap layer and partial copper layer, so that partial barrier layer is exposed. Finally, a further step of chemical mechanical polishing is performed to remove partial barrier layer and partial copper layer, so that partial dielectric layer is exposed and the multi-level copper interconnect is completed.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A shows a schematic cross-sectional diagram of a conventional copper interconnect;

FIG. 1B shows a schematic cross-sectional diagram of a conventional copper interconnect having a dishing phenomenon;

FIG. 2A shows a schematic cross-sectional diagram of a conventional copper interconnect with a passivation layer;

FIG. 2B shows a schematic cross-sectional diagram of a conventional copper interconnect with a passivation layer having a dishing phenomenon;

FIG. 3A through FIG. 3F provide cross-sectional views at various stages in an embodiment for forming a multi-level copper interconnect;

FIG. 4A through FIG. 4F provide cross-sectional views at various stages in another embodiment for forming a multi-level copper interconnect.

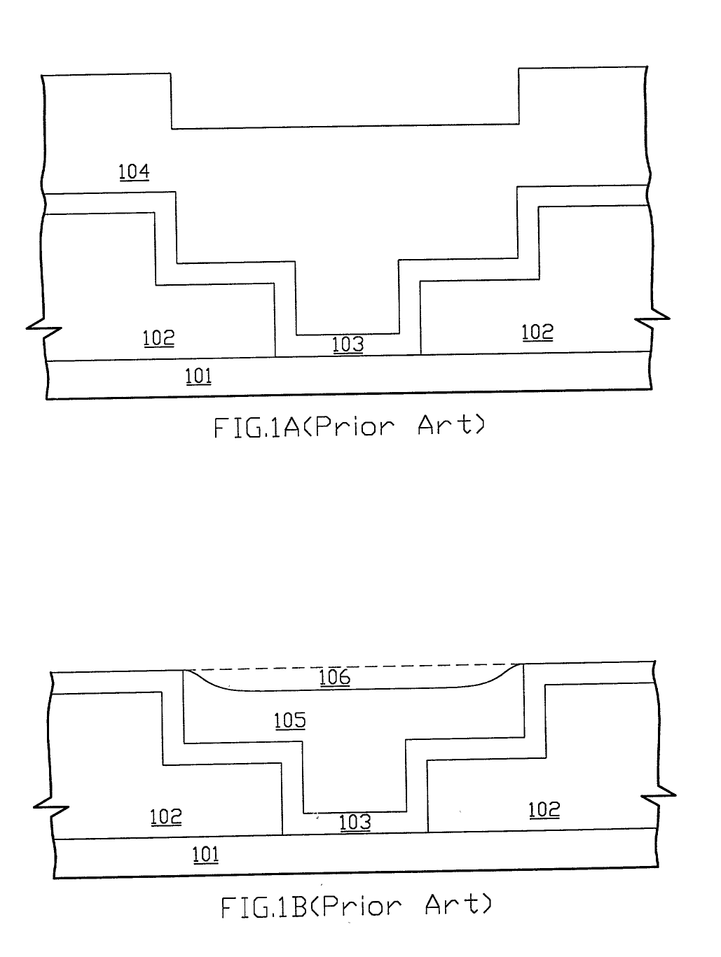

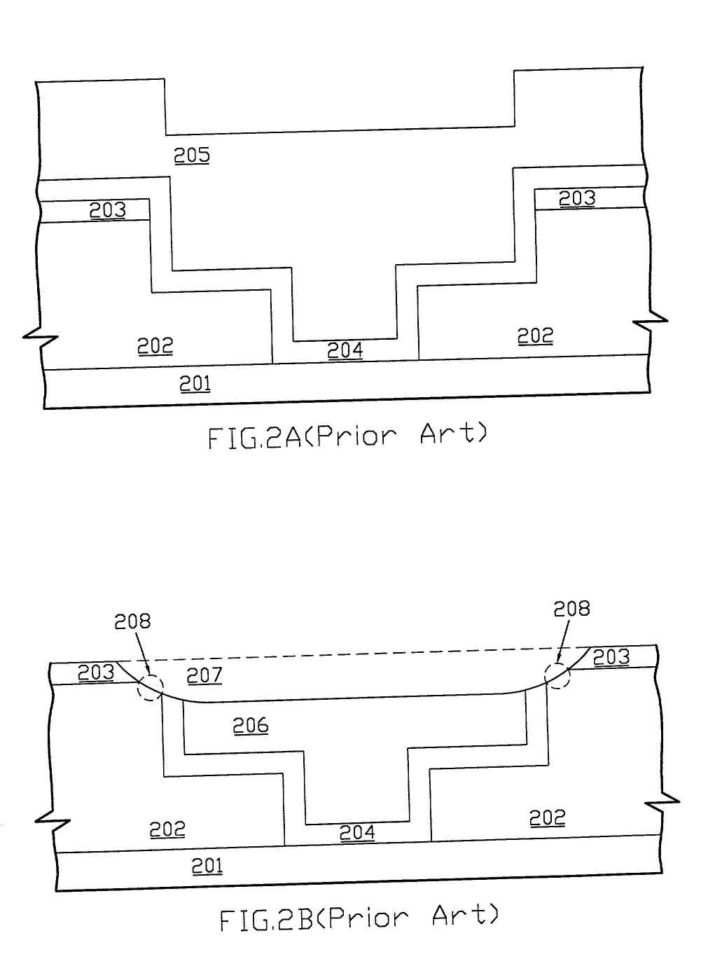

### DESCRIPTION OF THE PREFERRED EMBODIMENT

To solve the problem of dishing phenomenon on copper interconnect, we provide a method to balance the difference of polishing rate between the copper and the surrounding material by using a cap layer selectively positioned over the dual damascene structure. Such can get a plane surface in a chemical mechanical polishing.

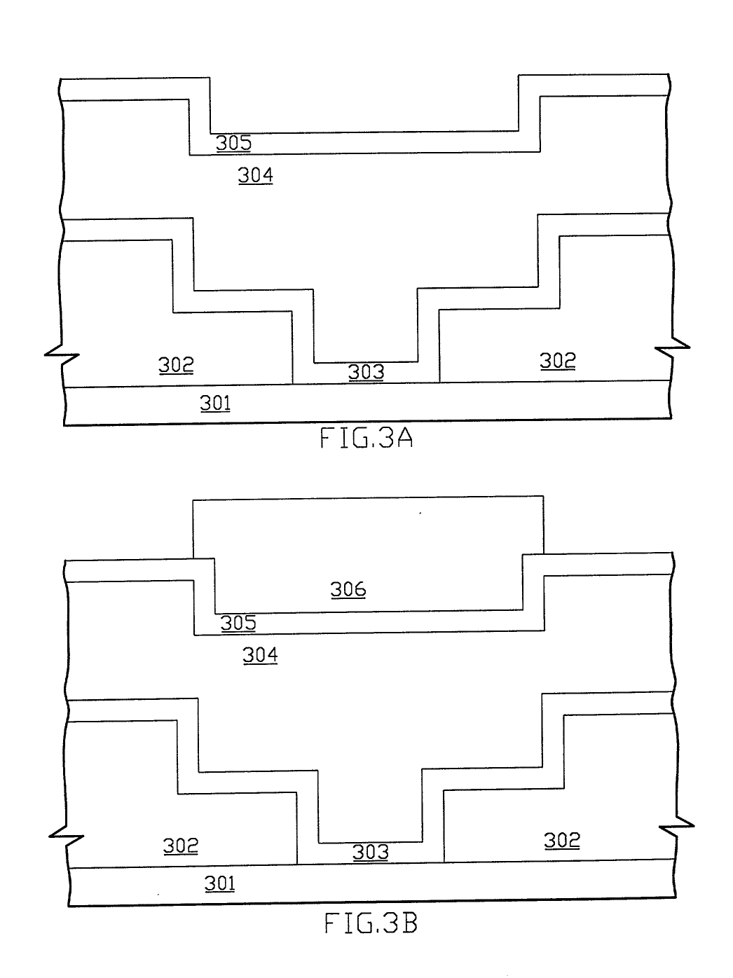

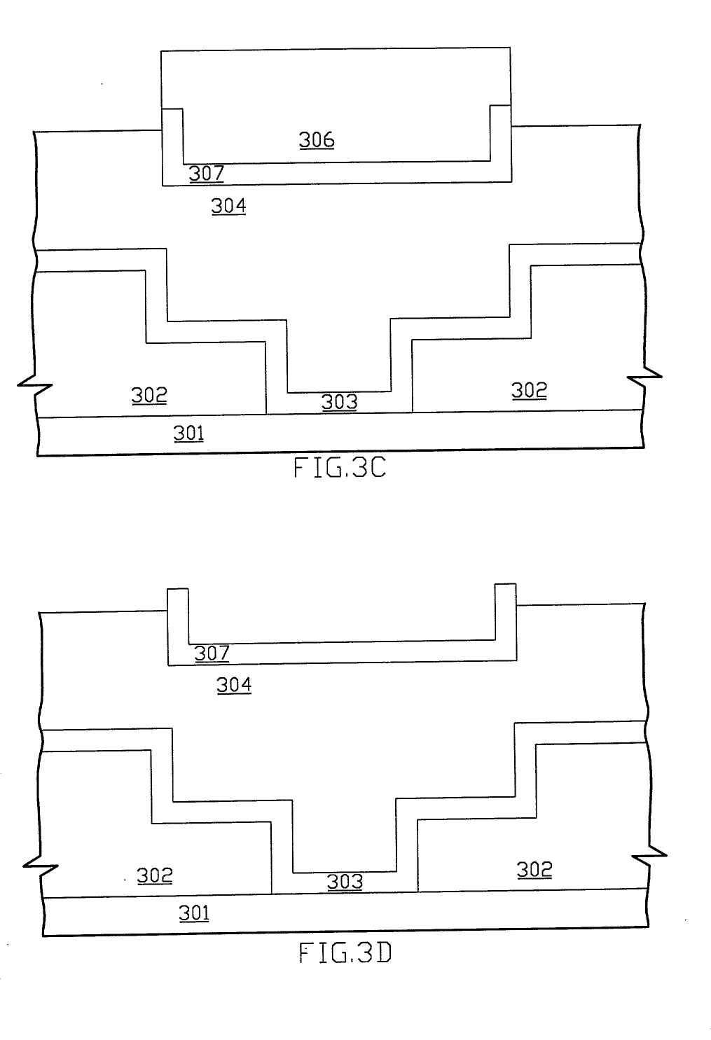

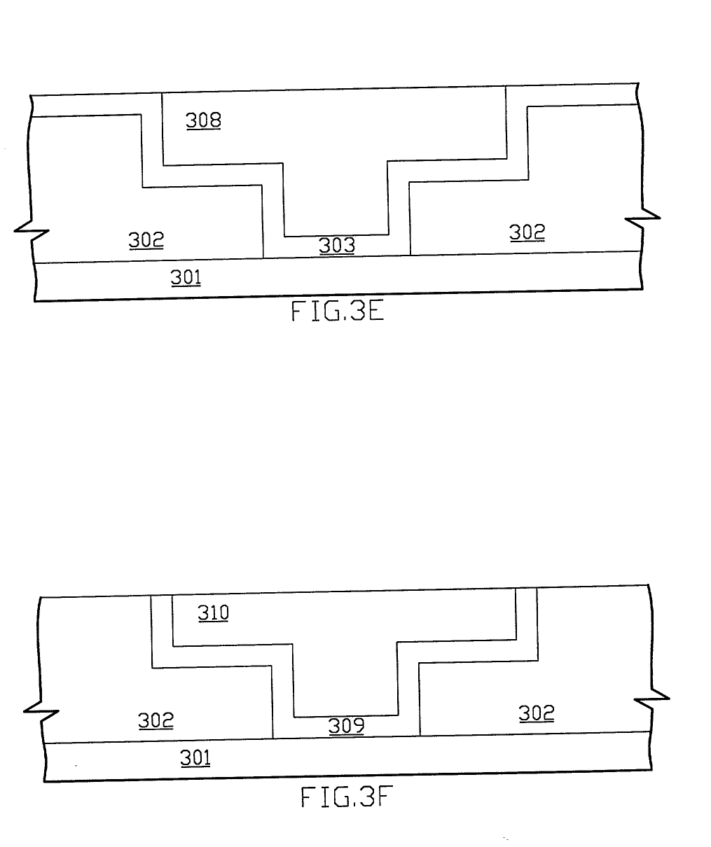

An embodiment we provide is shown in FIG. 3A to FIG. 3F. Firstly, as shown in FIG. 3A, there is a copper interconnect 301 over a substrate (not shown). Secondly, an insulating layer 302, such as silicon oxide, is deposited on the copper interconnect 301. Then, the insulating layer 302 is etched to form a dual damascene opening. Next, a barrier layer 303, such as tantalum and tantalum nitride, is deposited on the surface of the dual damascene opening. A copper layer 304 is then deposited to fill up the dual damascene opening. Next, a cap layer 305 is deposited on the surface of the copper layer 304. The material of the cap layer 305 can be metal, polysilicon, silicon oxide, silicon nitride, silicon carbide, spin-on glass, or low-K material. Then, a photoresist is deposited and patterned to form a photoresist mask 306, as shown in FIG. 3B. The photoresist mask 306 is over the dual damascene opening, and the width of the photoresist mask 306 is about equal to the width of the dual damascene opening. Next, an etching is performed to remove a part of the cap layer 305 which is not covered with the photoresist mask 306 and the residue 307 of the cap layer 305 is over the dual damascene opening, as shown in FIG. 3C. Then the photoresist mask 306 is removed, as shown in FIG. 3D. A chemical mechanical polishing is performed to remove the residue 307 of the cap layer 305 and partial copper layer 304 over the barrier layer 303, so partial barrier layer 303 is exposed and a dual damascene structure 308 is formed, as shown in FIG. 3E. Finally, a further step of chemical mechanical polishing is performed to remove partial barrier layer 303 and partial copper layer 304, so that partial insulating layer 302 is exposed and the multi-level copper interconnect is completed, as shown in FIG. 3F. In which, the copper dual damascene structure 310 and insulating layer 302 is separated by the barrier layer 309. The present method can form a multi-level copper interconnect with plate surface and avoid the dishing phenomenon and related problems

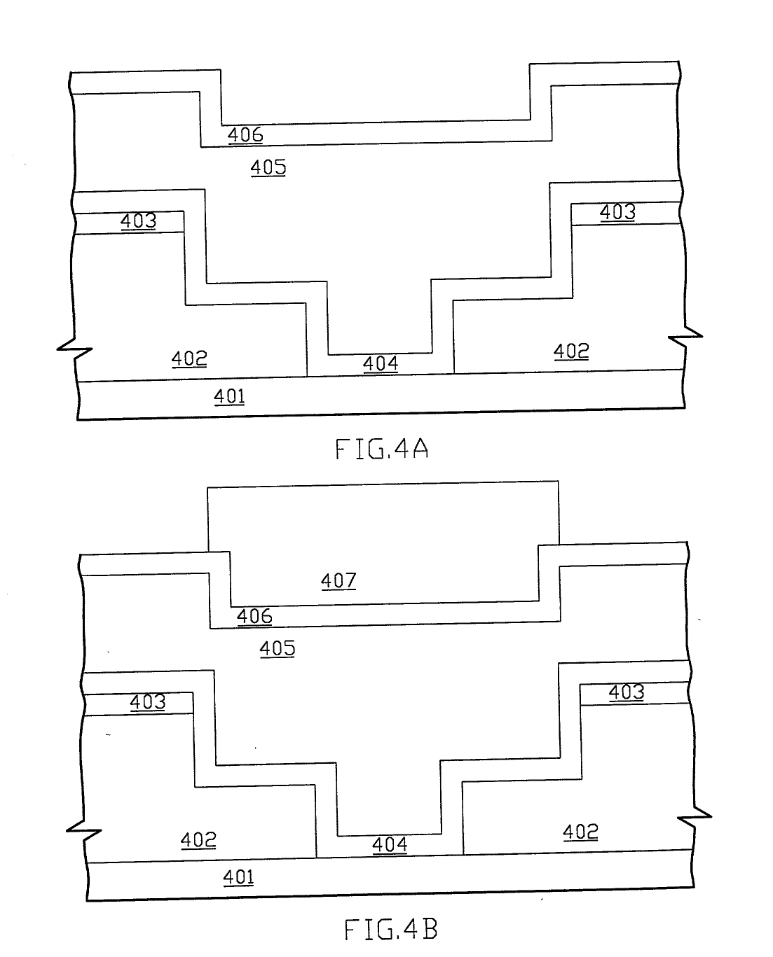

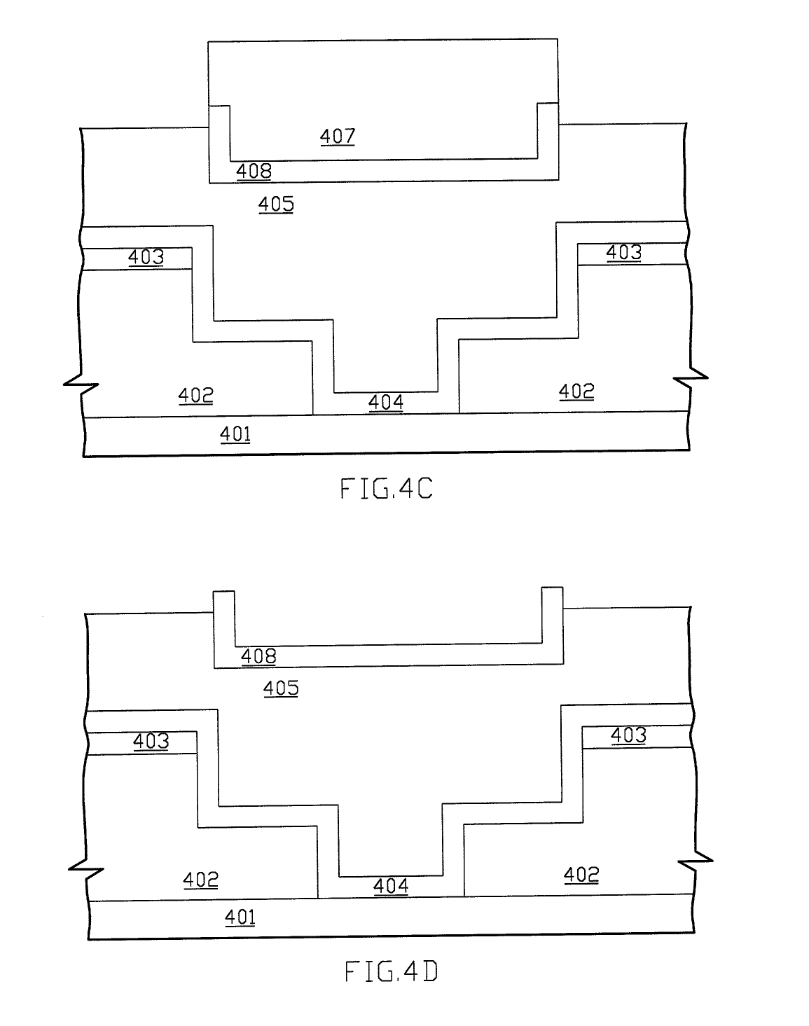

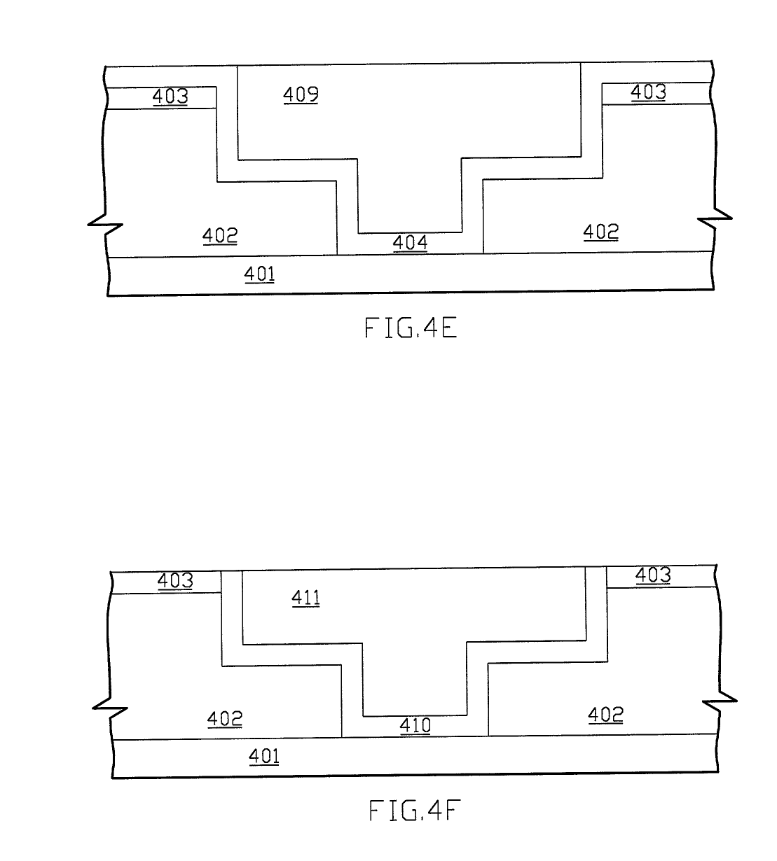

Another embodiment of the invention is shown in FIG. 4A to FIG. 4F. Firstly, as shown in FIG. 4A, there is a copper interconnect 401 over a substrate (not shown). Secondly, a dielectric layer 402, such as spin-on polymers which are aromatic hydrocarbons and carbon-doped silicon oxides which are formed by chemical vapor deposition, is deposited on the copper interconnect 401. The value of the dielectric constant of a low-K material is general less then about 4.0. Then a passivation layer 403, such as silicon nitride and silicon carbide, is deposited on the dielectric layer 402. Then, the dielectric layer 402 and the passivation layer 403 are etched to form a dual damascene opening. Next, a barrier layer 404, such as tantalum and tantalum nitride, is deposited on the surface of the dual damascene opening. A copper layer 405 is then deposited to fill up the dual damascene opening. Next, a cap layer 406 is deposited on the surface of the copper layer 405. The material of the cap layer 406 can be metal, polysilicon, silicon oxide, silicon nitride, silicon carbide, spin-on glass, or low-K material. Then, a photoresist is deposited and patterned to form a photoresist mask 407, as shown in FIG. 4B. The photoresist mask 407 is over the dual damascene opening, and the width of the photoresist mask 407 is about equal to the width of the dual damascene opening. Next, an etching is performed to remove a part of the cap layer 406 which is not covered with the photoresist mask 407 and the residue 408 of the cap layer 406 is over the dual damascene opening, as shown in FIG. 4C. Then, the photoresist mask 407 is removed, as shown in FIG. 4D. A chemical mechanical polishing is performed to remove the residue 408 of the cap layer 406 and partial copper layer 405 over the barrier layer 404, so that partial barrier layer 404 is exposed and a dual damascene structure 409 is formed, as shown in FIG. 4E. Finally, a further step of chemical mechanical polishing is performed to remove partial barrier layer 404 and partial copper layer 405, so that partial passivation layer 403 is exposed and the multi-level copper interconnect is completed, as shown in FIG. 4F. In which, the copper dual damascene structure 411 and the dielectric layer 402 is separated by the barrier layer 410.

Although specific embodiments have been illustrated and described, it will be obvious to those skilled in the art that various modifications may be made without departing from what is intended to be limited solely by the appended claims.

What is claimed is:

1. A method for forming a copper interconnect, said method comprising the steps of:
providing a structure, said structure comprises a copper interconnect;
depositing a dielectric layer on said copper interconnect;
etching said dielectric layer to form a dual damascene opening;
conformally depositing a barrier layer on the surface of said dual damascene opening;
depositing a copper layer on said barrier layer to fill up said dual damascene opening;
depositing a cap layer on the surface of said copper layer;
depositing a photoresist on said cap layer;
patterning said photoresist to form a photoresist mask, wherein said photoresist mask is over said dual damascene opening, and the width of said photoresist mask is about equal to the width of said dual damascene opening;
performing an etching to remove a part of said cap layer, wherein said part of said cap layer is not covered with said photoresist mask and the residue of said cap layer is over said dual damascene opening;
removing said photoresist mask;
performing a first chemical mechanical polishing to remove said residue of said cap layer and partial said copper layer, so that partial said barrier layer is exposed; and
performing a second chemical mechanical polishing to remove partial said barrier layer and partial said copper layer, so that partial said dielectric layer is exposed.

2. The method according to claim 1, wherein the material of said cap layer is selected from the group consisting of metal, polysilicon, silicon oxide, silicon nitride, silicon carbide, spin-on glass, and low-K materials.

3. The method according to claim 1, wherein the material of said barrier layer comprises tantalum.

4. The method according to claim 1, wherein the material of said barrier layer comprises tantalum nitride.

5. The method according to claim 1, wherein the material of said dielectric layer comprises silicon oxide.

6. The method according to claim 1, further comprising a passivation layer formed on said diectric layer.

7. The method according to claim 6, wherein the material of said passivation layer comprises silicon nitride.

8. The method according to claim 6, wherein the material of said passivation layer comprises silicon carbide.

9. A method for forming a copper interconnect, said method comprising the steps of:
providing a structure, said structure comprises a copper interconnect;
depositing a dielectric layer on said copper interconnect;
depositing a passivation layer on said dielectric layer;
etching said dielectric layer and said passivation layer to form a dual damascene opening;
conformally depositing a barrier layer on the surface of said dual damascene opening;
depositing a copper layer on said barrier layer to fill up said dual damascene opening;
depositing a cap layer on the surface of said copper layer;
depositing a photoresist on said cap layer;
patterning said photoresist to form a photoresist mask, wherein said photoresist mask is over said dual damascene opening, and the width of said photoresist mask is about equal to the width of said dual damascene opening;
performing an etching to remove a part of said cap layer, wherein said part of said cap layer is not covered with said photoresist mask and the residue of said cap layer is over said dual damascene opening;
removing said photoresist mask;
performing a first chemical mechanical polishing to remove said residue of said cap layer and partial said copper layer, so that partial said barrier layer is exposed; and
performing a second chemical mechanical polishing to remove partial said barrier layer and partial said copper layer, so that partial said passivation layer is exposed.

10. The method according to claim 9, wherein the material of said cap layer is selected from the group consisting of metal, polysilicon, silicon oxide, silicon nitride, silicon carbide, spin-on glass, and low-K materials.

11. The method according to claim 9, wherein the material of said barrier layer comprises tantalum.

12. The method according to claim 9, wherein the material of said barrier layer comprises tantalum nitride.

13. The method according to claim 9, wherein the material of said dielectric layer comprises silicon oxide.

14. The method according to claim 9, wherein the material of said dielectric layer comprises low-K materials, and the values of dielectric constant of said low-K materials are less then about 4.0.

15. The method according to claim 14, wherein said low-K materials comprise spin-on polymer low-K materials.

16. The method according to claim 14, wherein said spin-on polymer low-K materials comprise aromatic hydrocarbons.

17. The method according to claim 14, wherein said low-K materials are formed by a chemical vapor deposition.

18. The method according to claim 17, wherein said low-K materials which are formed by said chemical vapor deposition comprise carbon-doped silicon oxide.

19. The method according to claim 9, wherein the material of said passivation layer comprises silicon nitride.

20. The method according to claim 9, wherein the material of said passivation layer comprises silicon carbide.
